(19) United States
(12) Patent Application Publication
(10) Pub. No.: US 2026/0143979 A1
(43) Pub. Date: May 21, 2026

(54) SUBSTRATE PROCESSING METHOD

(71) Applicant: Tokyo Electron Limited, Tokyo (JP)

(72) Inventors: Tenta USHIDA, Yamanashi (JP); Tadashi MITSUNARI, Yamanashi (JP); Miyako KANEKO, Yamanashi (JP)

(21) Appl. No.: 19/448,856

(22) Filed: Jan. 14, 2026

Related U.S. Application Data
(63) Continuation of application No. PCT/JP2024/026643, filed on Jul. 25, 2024.

(30) Foreign Application Priority Data
Jul. 28, 2023 (JP) 2023-123540

(51) Int. Cl. H10P 14/69; C23C 16/26; C23C 16/503; C23C 16/56; H01J 37/32; H10P 14/60

(52) U.S. Cl. CPC H10P 14/6902; C23C 16/26; C23C 16/503; C23C 16/56; H01J 37/32449; H10P 14/6336; H01J 2237/3321

(57) ABSTRACT

A substrate processing method for forming a carbon-containing film that is inhibited from film peeling due to thermal treatment is provided. The substrate processing method includes: preparing a substrate having a foundation film; forming a carbon-containing film having a film density of 2 g/cm³ or greater on the foundation film by forming a plasma of a processing gas containing a carbon-containing gas; and subjecting the substrate on which the carbon-containing film is formed to thermal treatment. In the forming of the carbon-containing film, for a first time from a start of the forming of the carbon-containing film, an ion energy higher than the ion energy during a second time from an end of first time is supplied to the substrate.

### CROSS-REFERENCE TO RELATED APPLICATIONS

This application is a continuation application of International Application No. PCT/JP2024/026643, filed on Jul. 25, 2024, and designating the U.S., which is based upon and claims priority to Japanese Patent Application No. 2023-123540, filed on Jul. 28, 2023, the entire contents of which are incorporated herein by reference.

### BACKGROUND

### Technical Field

The present disclosure relates to a substrate processing method.

### Background Art

Japanese Patent Application Laid-Open Publication No. 2022-128270 discloses a substrate processing method for forming a carbon-based film on a substrate, which includes a step of mounting the substrate on a mounting table, a first film-forming step of forming a first carbon-based film having a first stress, a second film-forming step of forming a second carbon-based film having a second stress, and a third film-forming step of forming a laminate of the first carbon-based film and the second carbon-based film by repeating the first film-forming step and the second film-forming step, wherein the first stress and the second stress are in the same direction and the first stress and the second stress have different strengths.

Japanese Translation of PCT International Publication No. 2022-545720 discloses a method including: exposing a semiconductor substrate in a chamber to a process gas containing a hydrocarbon precursor gas and helium gas in substantially the absence of any other inert gases, to deposit an ashable hard mask film on the substrate by a plasma-enhanced chemical vapor deposition process, wherein the plasma enhanced chemical vapor deposition process includes maintaining a chamber pressure lower than 500 mTorr and igniting a plasma formed by a dual radio frequency plasma source containing a high-frequency component and a low-frequency component.

### SUMMARY

According to one aspect, a substrate processing method includes: preparing a substrate having a foundation film; forming a carbon-containing film having a film density of 2 g/cm³ or greater on the foundation film by forming a plasma of a processing gas containing a carbon-containing gas; and subjecting the substrate on which the carbon-containing film is formed to thermal treatment, wherein in the forming of the carbon-containing film, wherein in the forming of the carbon-containing film, for a first time from a start of the forming of the carbon-containing film, an ion energy higher than the ion energy during a second time from an end of the first time is supplied to the substrate.

### BRIEF DESCRIPTION OF THE DRAWINGS

FIG. 1 is a schematic cross-sectional view showing an example of a processing apparatus according to the present embodiment;

FIG. 2 is a flowchart showing an example of substrate processing according to the present embodiment;

FIG. 3 is an example of a time chart for a process for forming a carbon-containing film performed by a substrate processing apparatus according to the present embodiment;

FIG. 4 is an example of a schematic cross-sectional view of a substrate showing an example of a structure of a carbon-containing film formed by a substrate processing apparatus according to the present embodiment; and

FIG. 5 shows a result regarding film peeling in a case of performing an annealing process.

### DETAILED DESCRIPTION OF THE INVENTION

Hereinafter, an embodiment of the present disclosure will be described with reference to the accompanying drawings. In each of the drawings, the same components are denoted by the same reference numerals, and redundant descriptions may be omitted.

### Substrate Processing Apparatus 1

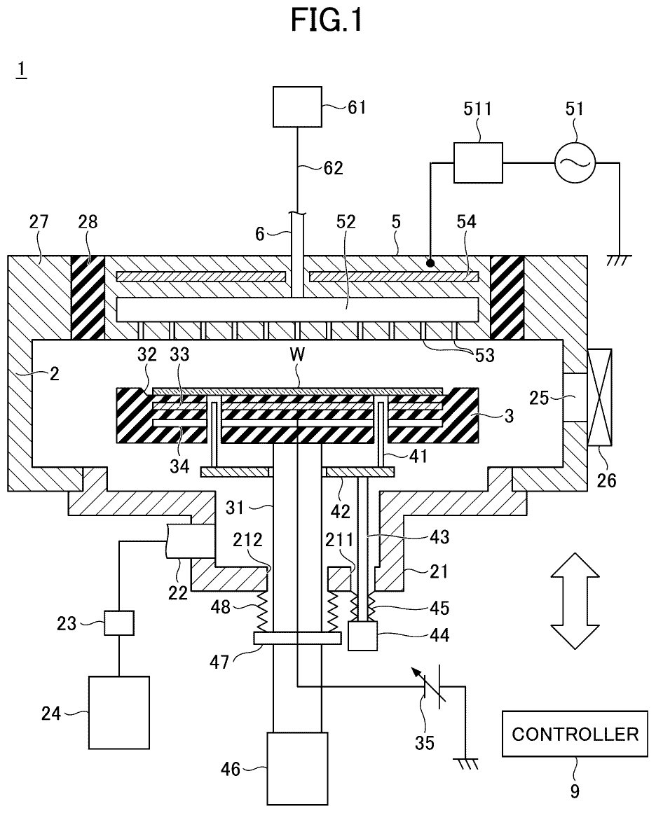

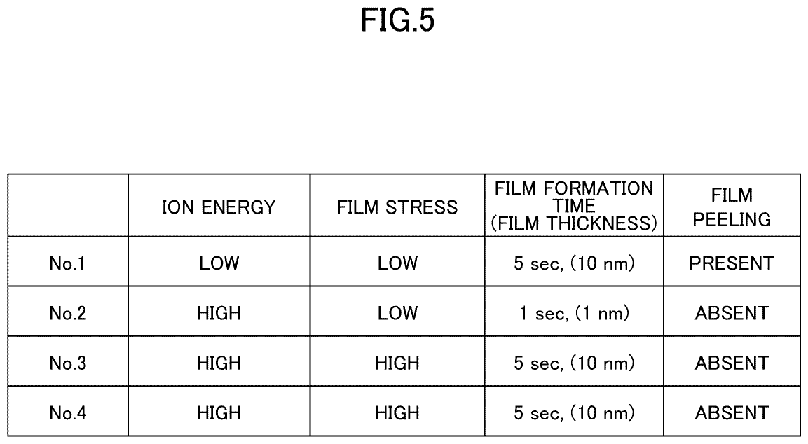

A substrate processing apparatus 1 according to the present embodiment will be described with reference to FIG. 1. FIG. 1 is a schematic cross-sectional view showing an example of a substrate processing apparatus 1 according to the present embodiment. The substrate processing apparatus 1 is an apparatus for forming a carbon-containing film 310 (see FIG. 4 described later) on a substrate W, such as a wafer and the like, by a Plasma-Enhanced Chemical Vapor Deposition (PECVD) method in a processing vessel 2 at reduced pressure.

The substrate processing apparatus 1 includes an airtight processing vessel 2 having a substantially cylindrical shape. A gas exhaust chamber 21 is provided in the center of a bottom wall of the processing vessel 2.

The gas exhaust chamber 21 has, for example, a substantially cylindrical shape projecting downward. A gas exhaust flow path 22 is connected to the gas exhaust chamber 21, for example, at a side surface of the gas exhaust chamber 21. A gas exhaust 24 is connected to the gas exhaust flow path 22 via a pressure regulator 23. The pressure regulator 23 includes, for example, a pressure regulator valve, such as a butterfly valve and the like. The gas exhaust flow path 22 is configured to allow the interior of the processing vessel 2 to be depressurized by the gas exhaust 24. A conveying opening 25 is provided in a side surface of the processing vessel 2. The conveying opening 25 is openable and closable by a gate valve 26. A substrate W is conveyed between the processing vessel 2 and a conveying chamber (not shown) via the conveying opening 25.

A mounting table 3 configured to hold the substrate W substantially horizontally is provided in the processing vessel 2. The mounting table 3 has a substantially circular shape in a plan view and is supported by a support member 31. A substantially circular recess 32 is formed in the surface of the mounting table 3 in order for a substrate W having a diameter of, for example, 300 mm to be mounted in the recess 32. The recess 32 has an inner diameter slightly (for example, by approximately 1 mm to 4 mm) greater than the diameter of the substrate W. The depth of the recess 32 is, for example, substantially the same as the thickness of the substrate W. The mounting table 3 is composed of a ceramic material, such as aluminum nitride (AlN) and the like. The mounting table 3 may be composed of a metal material, such as nickel (Ni) and the like. Instead of the recess 32, a guide ring for guiding the substrate W may be provided on the periphery of the surface of the mounting table 3.

A lower electrode 33 is embedded in the mounting table 3. A temperature regulating mechanism 34 is embedded under the lower electrode 33. The temperature regulating mechanism 34 regulates the substrate W mounted on the mounting table 3 to a set temperature based on a control signal from a controller 9. When the entirety of the mounting table 3 is composed of metal, the lower electrode 33 does not need to be embedded in the mounting table 3 because the entirety of the mounting table 3 functions as a lower electrode.

A power source for applying a bias voltage for drawing ions into the substrate W during plasma processing is connected to the lower electrode 33. In other words, the power source increases the energy of ions to be drawn into the substrate W. That is, the power source increases the ion energy to be supplied to the substrate W.

In the example shown in FIG. 1, a Direct-Current (DC) pulse power source 35 is connected to the lower electrode 33. The DC pulse power source 35 applies a DC pulse bias voltage to the lower electrode 33 in order to supply ion energy to the substrate W during plasma processing. The power source for supplying ion energy to the substrate W is not limited to this configuration. It may be a DC power source for applying a DC bias voltage to the lower electrode 33, or may be an RF power source for applying a low-frequency bias power. For example, the RF power source (not shown) is connected to the lower electrode 33 via a matcher (not shown). The RF power source applies a Low-Frequency (LF) power having a frequency lower than the frequency of an RF power source 51 described later to the lower electrode 33. A high-frequency power generated by the RF power source is used as a bias high-frequency power for drawing ions into the substrate W. The frequency of the RF power source is, for example, 13.56 MHz.

The mounting table 3 is provided with a plurality of (for example, three) lifting pins 41 for raising and lowering the substrate W mounted on the mounting table 3 while holding the substrate W. The material of the lifting pins 41 may be, for example, ceramics, such as alumina (Al2O3) and the like, quartz, and the like. The lower ends of the lifting pins 41 are attached to a support plate 42. The support plate 42 is connected to a lifting mechanism 44 provided outside the processing vessel 2 via a lifting shaft 43.

For example, the lifting mechanism 44 is provided under the gas exhaust chamber 21. A bellows 45 is provided between an opening 211 for the lifting shaft 43 formed in the lower surface of the gas exhaust chamber 21 and the lifting mechanism 44. The shape of the support plate 42 may be a shape that can be raised and lowered without interfering with the support member 31 of the mounting table 3. The lifting pins 41 are configured to be raised and lowered by the lifting mechanism 44 between the upper side of the surface of the mounting table 3 and the lower side of the surface of the mounting table 3. In other words, the lifting pins 41 are projectable from the upper surface of the mounting table 3.

The lower end of the support member 31 penetrates an opening 212 of the gas exhaust chamber 21 and is supported by a lifting mechanism 46 via a lifting plate 47 disposed under the processing vessel 2. A bellows 48 is provided between the bottom of the gas exhaust chamber 21 and the lifting plate 47, and the airtightness in the processing vessel 2 is maintained even against vertical movements of the lifting plate 47.

By the lifting mechanism 46 raising and lowering the lifting plate 47, the mounting table 3 can be raised and lowered. Thus, the gap between the mounting table 3 and a gas supply 5 can be adjusted.

A top wall 27 of the processing vessel 2 is provided with the gas supply 5 via an insulating member 28. The gas supply 5 constitutes an upper electrode and faces the lower electrode 33. The RF power source 51 is connected to the gas supply 5 via a matcher 511. The RF power source 51 applies high-frequency power to the upper electrode (gas supply 5). The high-frequency power generated by the RF power source 51 is used as a high-frequency power for formation of a plasma necessary for film formation on the substrate W. The frequency of the RF power source 51 is, for example, 40 MHz to 300 MHz. By supplying RF power from the RF power source 51 to the upper electrode (gas supply 5), an RF electric field is generated between the upper electrode (gas supply 5) and the lower electrode 33. The gas supply 5 includes a hollow gas diffusion chamber 52. In the lower surface of the gas diffusion chamber 52, a multitude of holes 53 for dispersively supplying the processing gas into the processing vessel 2 are, for example, uniformly arranged. For example, a heating mechanism 54 is embedded in the gas supply 5 above the gas diffusion chamber 52. The heating mechanism 54 is heated to a set temperature by being supplied with power from a power source (not shown) based on a control signal from the controller 9.

The gas diffusion chamber 52 is provided with a gas supply path 6. The gas supply path 6 communicates with the gas diffusion chamber 52. A gas source 61 is connected to the upstream side of the gas supply path 6 via a gas line 62. The gas source 61 includes, for example, supply sources of various processing gases, a mass flow controller, and valves (none of which are shown). The various processing gases include a film-forming gas (at least one selected from CxHy (x and y are desirable integers), such as CH₄, C₂H₂, C₃H₆, C₂H₄, and the like) containing a carbon atom used in the above-described method for forming a carbon-based film. The various processing gases may also include a carrier gas (for example, at least one selected from H₂, Ar, He, O₂, and N₂). The various processing gases are introduced into the gas diffusion chamber 52 from the gas source 61 via the gas line 62.

The substrate processing apparatus 1 includes the controller 9. The controller 9 is, for example, a computer, and includes a Central Processing Unit (CPU), a Random Access Memory (RAM), a Read Only Memory (ROM), an auxiliary storage device, and the like. The CPU operates based on a program stored in the ROM or the auxiliary storage device, and controls the operation of the substrate processing apparatus 1. The controller 9 may be provided inside or outside the substrate processing apparatus 1. When the controller 9 is provided outside the substrate processing apparatus 1, the controller 9 can control the substrate processing apparatus 1 by a wired, wireless, and any other communication method.

### Substrate Processing

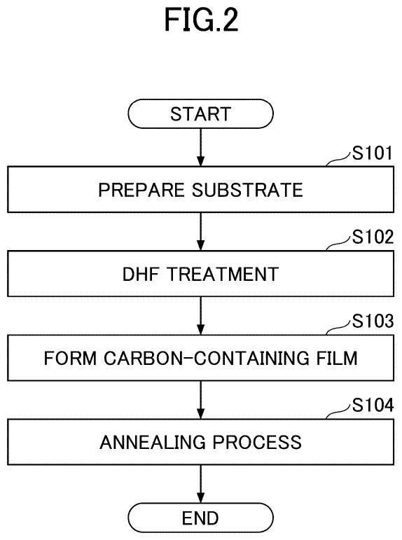

Next, an example of substrate processing according to the present embodiment will be described with reference to FIG. 2. FIG. 2 is a flowchart showing an example of the substrate processing according to the present embodiment.

In step S101, a substrate W is prepared. A foundation film 300 (see FIG. 4) is formed on the substrate W. The foundation film 300 is a silicon-containing film containing, for example, silicon (Si). The foundation film 300 is any one of Si, SiO₂, SiN, SiC, SiON, SiCON, or the like. The foundation film 300 may be a metal-containing film containing a metal atom. The metal atom of the metal-containing film may be any one of Ti, Ta, Zr, Hf, or the like. The foundation film 300 is any one of TiN, TaN, ZrN, HfN, or the like.

In step S102, the substrate W having the foundation film 300 is subjected to DHF treatment. Here, DHF (diluted HF) is supplied to the surface of the substrate W having the foundation film 300 (see FIG. 4), to subject the surface of the foundation film 300 to wet etching processing. In this way, the surface of the foundation film 300 is cleaned. Further, a natural oxide film (not shown) formed on the surface of the foundation film 300 is removed. The process shown in step S102 is not essential and may be omitted.

In step S103, a carbon-containing film 310 (see FIG. 4) is formed on the substrate W having the foundation film 300. The carbon-containing film 310 is, for example, an amorphous carbon film. The carbon-containing film 310 is, for example, a Diamond Like Carbon (DLC) film. The carbon-containing film 310 is a high-density carbon-containing film having a film density of 2 g/cm³ or greater. The high-density carbon-containing film 310 has a high etching resistance. Therefore, the carbon-containing film 310 can be used, for example, as a hard mask for etching the foundation film 300. The carbon-containing film 310 has a film thickness of 3 nm or greater. Therefore, the carbon-containing film 310 has a high film stress by having the high density and the film thickness of 3 nm or greater. The film stress of the carbon-containing film 310 is 1 GPa or greater.

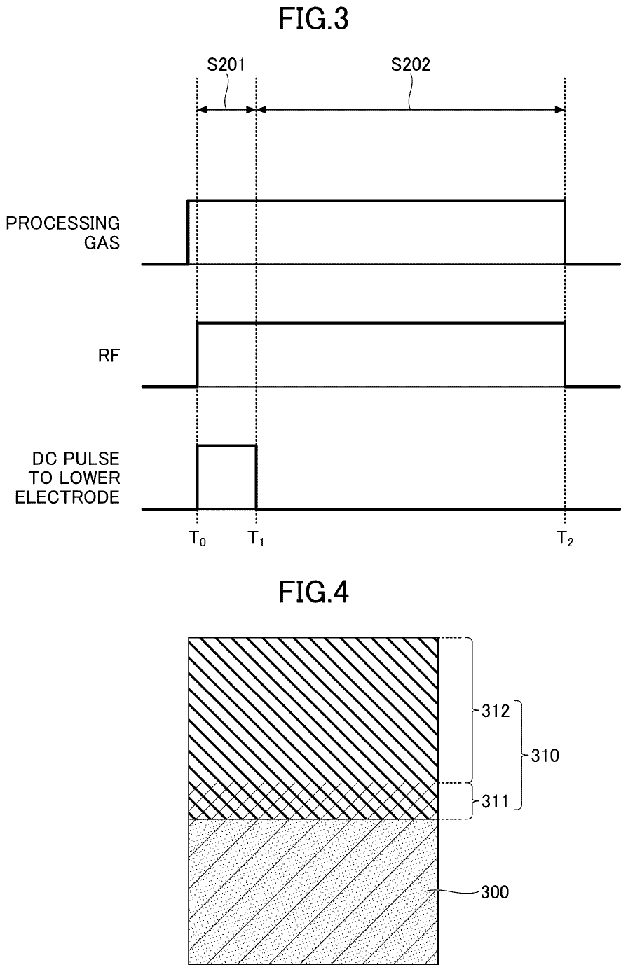

Here, the carbon-containing film 310 is formed on the foundation film 300 of the substrate W using the substrate processing apparatus 1 shown in FIG. 1. The method for forming the carbon-containing film 310 according to the present embodiment will be described later with reference to FIGS. 3 and 4.

In step S104, the substrate W on which the carbon-containing film 310 is formed is annealed (thermally treated). For example, the substrate W is heated at an annealing temperature in the range of 400° C. to 800° C. in an N₂ atmosphere at the atmospheric pressure or at a pressure lower than atmospheric pressure, to anneal the substrate W. The annealing of the substrate W reduces hydrogen (H) in the carbon-containing film 310, thereby reducing the film stress. The pressure lower than atmospheric pressure is, for example, a pressure in the range of 1 Torr to 700 Torr.

The flowchart of the substrate processing method according to the present embodiment shown in FIG. 2 has been described as performing the step of annealing the substrate W (step S104) after the step of forming the carbon-containing film 310 on the substrate W (step S103). However, this is non-limiting. Other processes may be added after the step S103 and before the step S104. Other processes may be added after the step S104.

Here, the carbon-containing film 310 formed by the PECVD method in the step S103 has a high film stress. Therefore, the film stress of the carbon-containing film 310 is reduced by performing the annealing process in the step S104. Further, the higher the annealing temperature, the more the film stress of the carbon-containing film 310 is reduced

On the other hand, in the case of the carbon-containing film 310 having a high density of 2 g/cm³ or greater, if the substrate W is annealed at a high temperature of 400° C. or higher, there is a risk of film peeling, in which the carbon-containing film 310 is peeled from the foundation film 300 of the substrate W during the annealing process.

Next, the process for forming the carbon-containing film 310 performed by the substrate processing apparatus 1 according to the present embodiment in step S103 will be described with reference to FIGS. 3 and 4.

FIG. 3 is an example of a time chart of the process for forming the carbon-containing film 310 performed by the substrate processing apparatus 1 according to the present embodiment. FIG. 4 is an example of a schematic cross-sectional view of the substrate W, showing an example of the structure of the carbon-containing film 310 formed by the substrate processing apparatus 1 according to the present embodiment.

The controller 9 controls a conveying device (not shown) to mount the substrate W on the mounting table 3 of the substrate processing apparatus 1. The substrate processing apparatus 1 forms the carbon-containing film 310 on the foundation film 300 of the substrate W. The carbon-containing film 310 is used as, for example, a hard mask. The foundation film 300 is a film in which a structure, such as a trench, a channel, a hole, and the like is formed by being subjected to dry etching through a pattern formed in the carbon-containing film 310. When the conveying device retreats from the conveying opening 25, the controller 9 closes the gate valve 26.

Further, the controller 9 controls the temperature regulating mechanism 34 to regulate the temperature of the substrate W to a predetermined temperature. Further, the temperature regulating mechanism 34 controls the pressure regulator 23 and the gas exhaust 24 to regulate the interior of the processing vessel 2 to a predetermined pressure.

Next, the controller 9 forms a carbon-containing film 310 on the substrate W. First, the controller 9 controls the gas source 61 to supply processing gases into the processing vessel 2. Here, as the processing gases, a carbon-containing gas (for example, C₂H₂ gas), an inert gas (for example, Ar gas), and the like are supplied into the processing vessel 2. Further, an additive gas (for example, H₂ gas) may be supplied as a processing gas.

In step S201 of FIG. 3, the controller 9 controls the RF power source 51 to apply a high-frequency power for plasma formation to the upper electrode (gas supply 5). At the same time, the controller 9 controls the DC pulse power source 35 to apply a DC pulse bias voltage (bias voltage) to the lower electrode 33. In other words, the ion energy to be supplied to the substrate W is controlled to be higher than that in step S202 described later. The processing gases are continuously supplied into the processing vessel 2. Thus, as shown in FIG. 4, an initial layer 311 of the carbon-containing film 310 is formed on the foundation film 300 in step S201. That is, the initial layer 311 of the carbon-containing film 310 is a part of the carbon-containing film 310 that is formed in the step S201.

An example of the recipe in step S201 is shown.

Pressure in the processing vessel: 5 mTorr to 1 Torr

Amount of carbon-containing gas supplied: 10 sccm to 1,500 sccm

Amount of inert gas supplied: 100 sccm to 2,000 sccm

RF power: 100 W to 2,000 W

DC pulse: 0.1 kV to 2 kV, duty ratio of 10% to 90%

The period in which the processing in step S201 is performed is a period until a first time T₁ elapses from the start T₀ of formation of the carbon-containing film 310. The start T₀ of formation is, for example, a timing at which the RF is applied. Here, the processing time in step S201 (the period until the first time T₁ elapses from the start T₀ of formation) is preferably in the range of 1 second to 10 seconds. The film thickness of the initial layer 311 is preferably in the range of 1 nm to 10 nm.

When the first time T₁ has elapsed, the process of the controller 9 proceeds to step S202.

In step S202 of FIG. 3, the controller 9 controls the DC pulse power source 35 to stop the DC pulse bias voltage (bias voltage) applied to the lower electrode 33. In other words, the ion energy to be supplied to the substrate W is controlled to be lower than that in step S201. The processing gases are supplied into the processing vessel 2 and the high-frequency power for plasma formation is applied to the upper electrode (gas supply 5) continuously from step S201. Thus, as shown in FIG. 4, a main body layer 312 of the carbon-containing film 310 is formed in step S202 to continue from the initial layer in step S202. That is, the main body layer 312 of the carbon-containing film 310 is a part of the carbon-containing film 310 that is formed in step S202.

An example of the recipe in step S202 is shown.

Pressure in the processing vessel: 5 mTorr to 1 Torr

Amount of carbon-containing gas supplied: 10 sccm to 1,500 sccm

Amount of inert gas supplied: 100 sccm to 2,000 sccm

RF power: 100 W to 2,000 W

As described above, the presence or absence of a bias voltage to be applied to the lower electrode 33 is the difference between the processing in step S201 and the processing in step S202, and other conditions are the same. That is, in the processing in step S201 and the processing in step S202, the processing pressure (pressure in the processing vessel) is the same pressure, the flow rates of the processing gases (amount of the carbon-containing gas supplied and amount of the inert gas supplied) are the same flow rates, and the power (RF power) for plasma formation is the same power.

The period in which the processing in step S202 is performed is a period until a second time T₂ elapses from the end of the first time T₁.

The period until the first time T₁ elapses from the start T₀ of formation is shorter than the period until the second time T₂ elapses from the end of the first time T₁. The film thickness of the carbon-containing film 310 formed in the period until the first time T₁ elapses from the start T₀ of formation is less than the film thickness of the carbon-containing film 310 formed in the period until the second time T₂ elapses from the end of the first time T₁. That is, the initial layer 311 is formed to have a film thickness less than the film thickness of the main body layer 312.

Here, the initial layer 311 formed in step S201 is formed by supplying a high ion energy to the substrate W. Here, the ion energy supplied to the substrate W in step S201 is preferably in the range of 100 eV to 2,000 eV.

When forming the initial layer 311, supplying a high ion energy to the substrate W strengthens the bonding between the carbon (C) supplied from the carbon-containing gas (for example, C₂H₂ gas) and the silicon (Si) of the foundation film 300. By strengthening the bonding at the interface between the carbon-containing film 310 and the foundation film 300, it is considered possible to inhibit film peeling of the carbon-containing film 310 during the annealing process.

When forming the initial layer 311, it is enough as long as a high ion energy can be supplied to the substrate W, and the bias voltage to be supplied to the lower electrode 33 is not limited to a DC pulse bias voltage. It may be a DC bias voltage or a low-frequency bias power.

When the bias voltage supplied to the lower electrode 33 is a DC pulse bias voltage, the following ranges are preferable.
0.1 kV to 2.0 kV
100 kHz to 250 kHz
duty ratio of 10% to 30%

When the bias voltage supplied to the lower electrode 33 is a DC bias voltage, the following range is preferable.
0.1 kV to 2.0 kV

When the bias voltage supplied to the lower electrode 33 is a low-frequency bias power, the following ranges are preferable.
400 kHz to 13.56 MHz
100 W to 4,000 W

When forming the main body layer 312, the ion energy to be supplied to the substrate W is reduced. Thus, the film density of the carbon-containing film 310 (main body layer 312) can be increased.

Next, an example of experimental results will be described with reference to FIG. 5. FIG. 5 is an example of the results of formation of various carbon-containing films. Here, the conditions for forming the initial layer 311 in step S201 (ion energy, film stress, and film formation time (film thickness)) and the result regarding film peeling through the annealing process are shown.

In No. 1, the initial layer 311 of the carbon-containing film 310 was formed on the substrate W subjected to the DHF treatment shown in step S102 of FIG. 2 under the conditions that the film stress of the initial layer 311 of the carbon-containing film 310 would become a low stress and the ion energy was low (the condition without DC application). That is, under the conditions that the RF power was a first power (for example, 100 W), the DC to be applied was a first voltage (for example, 0 V), and the pressure was a first pressure (for example, 100 mTorr), the initial layer 311 of the carbon-containing film 310 was formed for a processing time of 5 seconds (sec) in step S201 such that the initial layer 311 would have a film thickness of 10 nm. The film stress of the initial layer 311 when only the initial layer 311 was formed to a thickness of 50 nm under these conditions was −280 MPa. Thereafter, the main body layer 312 of the carbon-containing film 310 was formed to a thickness of 40 nm continuously from the initial layer 311. As the main body layer 312 of the carbon-containing film 310, a high-stress film was formed under the conditions that the RF power was a second power (for example, 300 W) higher than the first power, the DC applied was the first voltage (for example, 0 V), and the pressure was a second pressure (for example, 20 mTorr) lower than the first pressure.

In No. 2, the initial layer 311 of the carbon-containing film 310 was formed on the substrate W subjected to the DHF treatment shown in step S102 of FIG. 2 under conditions that the film stress of the initial layer 311 of the carbon-containing film 310 would become a low stress and the ion energy was high (the condition with DC application). That is, the initial layer 311 of the carbon-containing film 310 was formed under conditions that the RF power was the first power (for example, 300 W), the DC applied was the first voltage for supplying a high ion energy (for example, 2 kV), and the pressure was the first pressure (for example, 20 mTorr) for a processing time of 1 second (sec) in step S201 such that the initial layer 311 would have a film thickness of 1 nm. The film stress when only the initial layer 311 was formed to a thickness of 50 nm under these conditions was −0.5 GPa. The film stress of the initial layer 311 of No. 2 when formed to a thickness of 50 nm was higher than the film stress of the initial layer 311 of No. 1 formed to a thickness of 50 nm. The initial layer 311 of No. 2 was formed as a low-stress film by being formed with a small film thickness. Thereafter, the main body layer 312 of the carbon-containing film 310 was formed to a thickness of 40 nm continuously from the initial layer 311. As the main body layer 312 of the carbon-containing film 310, a high-stress film was formed under the conditions that the DC applied was a second voltage (for example, 0 V) for supplying a low ion energy, which was lower than the first voltage, and the RF power and the pressure were the same as those for the initial layer 311.

In No. 3, the initial layer 311 of the carbon-containing film 310 was formed on the substrate W subjected to the DHF treatment shown in step S102 of FIG. 2 under the conditions that the film stress of the initial layer 311 of the carbon-containing film 310 would be a high stress and the ion energy was high (the condition with DC application). That is, the initial layer 311 of the carbon-containing film 310 was formed under the conditions that the RF power was the first power (for example, 300 W), the DC applied was the first voltage for supplying a high ion energy (for example, 1 kV), and the pressure was the first pressure (for example, 20 mTorr) for a processing time of 5 seconds (sec) in step S201, such that the initial layer 311 would have a film thickness of 10 nm. The film thickness of the initial layer 311 when only the initial layer 311 was formed to a thickness of 50 nm under these conditions was −1 GPa. Thereafter, the main body layer 312 of the carbon-containing film 310 was formed to a thickness of 40 nm continuously from the initial layer 311. As the main body layer 312 of the carbon-containing film 310, a high-stress film was formed under the conditions that the DC applied was the second voltage (for example, 0 V) for supplying a low ion energy, which was lower than the first voltage, and the RF power and the pressure were the same as those for the initial layer 311.

In No. 4, the DHF treatment shown in step S102 of FIG. 2 was omitted, and except for this, the initial layer 311 of the carbon-containing film 310 was formed under the same conditions as No. 3. Thereafter, the main body layer 312 of the carbon-containing film 310 was formed to a thickness of 40 nm continuously from the initial layer 311.

FIG. 5 shows the result regarding film peeling in the case of performing annealing at 600° C. As shown in FIG. 5, in No. 1, film peeling of the carbon-containing film 310 occurred.

On the other hand, in No. 2, film peeling of the carbon-containing film 310 did not occur even though the film stress of the initial layer 311 increased as compared with No. 1.

In No. 3, film peeling of the carbon-containing film 310 did not occur even though the film thickness of the initial layer 311 was greater than that in No. 2, in other words, even though the film stress of the initial layer 311 was higher than that in No. 2.

In No. 4, film peeling of the carbon-containing film 310 did not occur even in spite of the omission of the DHF treatment.

As described above, according to the substrate processing method according to the present embodiment, by supplying ion energy to the substrate W in the initial stage of formation of the carbon-containing film 310, it is possible to inhibit film peeling of the carbon-containing film 310 in the annealing process.

The substrate processing method for forming the carbon-containing film 310 has been described above. However, the present disclosure is not limited to the above-described embodiments and the like, and various modifications and improvements are applicable within the scope of the spirit of the present disclosure described in the claims.

According to one aspect, it is possible to provide a substrate processing method for forming a carbon-containing film that is inhibited from film peeling due to thermal treatment.

What is claimed is:

1. A substrate processing method, comprising:
preparing a substrate having a foundation film;
forming a carbon-containing film having a film density of 2 g/cm³ or greater on the foundation film by forming a plasma of a processing gas containing a carbon-containing gas; and
subjecting the substrate on which the carbon-containing film is formed to thermal treatment,
wherein, in the forming of the carbon-containing film, for a first time from a start of the forming of the carbon-containing film, an ion energy higher than the ion energy during a second time from an end of the first time is supplied to the substrate.

2. The substrate processing method according to claim 1,
wherein for the first time from the start of the forming of the carbon-containing film, a bias voltage is applied to a lower electrode provided in a mounting table supporting the substrate.

3. The substrate processing method according to claim 2,
wherein the bias voltage is any of a Direct-Current (DC) pulse bias voltage, a DC bias voltage, or a low-frequency bias power.

4. The substrate processing method according to claim 2,
wherein the bias voltage is a DC pulse bias voltage in a range of 0.1 kV to 2.0 kV, a range of 100 kHz to 250 kHz, and a duty ratio range of 10% to 30%.

5. The substrate processing method according to claim 2,
wherein the bias voltage is a DC bias voltage in a range of 0.1 kV to 2.0 kV.

6. The substrate processing method according to claim 2,
wherein the bias voltage is a low-frequency bias power in a range of 400 kHz to 13.56 MHz and a range of 100 W to 4,000 W.

7. The substrate processing method according to claim 1,
wherein the ion energy is in a range of 100 eV to 2,000 eV.

8. The substrate processing method according to claim 1,
wherein the first time from the start of the forming of the carbon-containing film is shorter than the second time from the end of the first time.

9. The substrate processing method according to claim 8,
wherein the first time from the start of the forming of the carbon-containing film is in a range of 1 second to 10 seconds.

10. The substrate processing method according to claim 1,
wherein a film thickness of the carbon-containing film formed in the first time from the start of the forming of the carbon-containing film is less than a film thickness of the carbon-containing film formed in the second time from the end of the first time.

11. The substrate processing method according to claim 10,
wherein the film thickness of the carbon-containing film formed in the first time from the start of the forming of the carbon-containing film is in a range of 1 nm to 10 nm.

12. The substrate processing method according to claim 1,
wherein a processing pressure in the first time from the start of the forming of the carbon-containing film and a processing pressure in the second time from the end of the first time are the same pressure.

13. The substrate processing method according to claim 1,
wherein a flow rate of the processing gas in the first time from the start of the forming of the carbon-containing film and a flow rate of the processing gas in the second time from the end of the first time are the same flow rate.

14. The substrate processing method according to claim 12,
wherein an electric power for forming the plasma in the first time from the start of the forming of the carbon-containing film and an electric power for forming the plasma in the second time from the end of the first time are the same electric power.

15. The substrate processing method according to claim 1,
wherein the carbon-containing gas is at least one selected from CH₄, C₂H₂, C₃H₆, and C₂H₄.

16. The substrate processing method according to claim 1,
wherein the processing gas further contains an inert gas, and
wherein the inert gas is at least one selected from H₂, Ar, He, O₂, and N₂.

17. The substrate processing method according to claim 1,
wherein the thermal treatment is performed at a temperature in a range of 400° C. to 800° C.

18. The substrate processing method according to claim 17,
wherein the thermal treatment is performed at an atmospheric pressure in an N₂ atmosphere.

19. The substrate processing method according to claim 17,
wherein the thermal treatment is performed at a pressure in a range of 1 Torr to 700 Torr in an N₂ atmosphere.

20. The substrate processing method according to claim 1,
wherein the foundation film is a silicon-containing film or a metal-containing film.
